(19) United States
(12) Patent Application Publication
(10) Pub. No.: US 2017/0003808 A1
(43) Pub. Date: Jan. 5, 2017

(54) TRANSPARENT CONDUCTOR, METHOD OF FABRICATING THE SAME AND OPTICAL DISPLAY INCLUDING THE SAME

(71) Applicant: SAMSUNG SDI CO., LTD., Yongin-si (KR)

(72) Inventors: YoungHoon KIM, Suwon-si (KR); DaeSeob SHIM, Suwon-si (KR); KyoungKu KANG, Suwon-si (KR); DoYoung KIM, Suwon-si (KR); DongMyeong SHIN, Suwon-si (KR); JiHyeon YIM, Suwon-si (KR); OhHyeon HWANG, Suwon-si (KR)

(21) Appl. No.: 15/194,674

(22) Filed: Jun. 28, 2016

(30) Foreign Application Priority Data
Jun. 30, 2015 (KR) 10-2015-0093809
Jun. 27, 2016 (KR) 10-2016-0080351

(51) Int. Cl. G06F 3/041; H01L 27/32; G06F 3/042; H01L 51/52

(52) U.S. Cl. CPC G06F 3/0416; H01L 51/5253; H01L 51/5259; H01L 27/3258; H01L 51/5293; H01L 27/323; G06F 3/0412; G06F 3/0421; H01L 2251/5315; G06F 2203/04102; G06F 2203/04103

(57) ABSTRACT

A transparent conductor, a method of fabricating the same, and an optical display including the same, the transparent conductor including a base layer; and a conductive layer on the base layer, wherein the conductive layer includes metal nanowires and a matrix, and the transparent conductor has a haze of about 1.2% or less, a total transmittance of about 88% or more, a transmittance b* value of about 1.10 or less, as measured at a wavelength of 400 nm to 700 nm, and a sheet resistance of about 50 Ω/□ or less.

### CROSS-REFERENCE TO RELATED APPLICATION

Korean Patent Application No. 10-2015-0093809, filed on Jun. 30, 2015, in the Korean Intellectual Property Office, and entitled: “Transparent Conductor, Method of Fabricating the Same and Optical Display Including the Same,” and Korean Patent Application No. 10-2016-0080351, filed on Jun. 27, 2016 in the Korean Intellectual Property Office, are incorporated by reference herein in their entirety.

### BACKGROUND

1. Field

Embodiments relate to a transparent conductor, a method of fabricating the same, and an optical display including the same.

2. Description of the Related Art

Transparent conductors may be used in various fields such as touchscreen panels included in displays, flexible displays and the like. Although transparent conductors may be formed through deposition of an ITO film onto a PET film, a transparent conductor including metal nanowires, e.g., silver nanowires, may be due to good flexibility thereof.

### SUMMARY

Embodiments are directed to a transparent conductor, a method of fabricating the same, and an optical display including the same.

The embodiments may be realized by providing a transparent conductor including a base layer; and a conductive layer on the base layer, wherein the conductive layer includes metal nanowires and a matrix, and the transparent conductor has a haze of about 1.2% or less, a total transmittance of about 88% or more, a transmittance b* value of about 1.10 or less, as measured at a wavelength of 400 nm to 700 nm, and a sheet resistance of about 50Ω/□ or less.

The transparent conductor may have a sheet resistance change rate of about 10.0% or less, as calculated by Equation 1:

Sheet resistance change rate=|b−a|/a×100, [Equation 1]
wherein, in Equation 1, a is initial sheet resistance of the transparent conductor, and b is sheet resistance of the transparent conductor after being left under conditions of 85° C. and 85% relative humidity for 240 hours.

The metal nanowires may include silver, copper, platinum, tin, iron, nickel, cobalt, aluminum, zinc, indium, or titanium.

The transparent conductor may further include an overcoating layer on the conductive layer.

The transparent conductor may further include a hard coating layer, an anti-corrosion layer, an anti-reflection layer, an anti-glare layer, an adhesion enhancing layer, or a barrier layer, on one or both surfaces of the base layer.

The embodiments may be realized by providing a method of fabricating a transparent conductor, the method including forming a metal nanowire network on a base layer using a conductive composition; and forming a conductive layer on the metal nanowire network using a matrix composition, wherein the conductive composition includes an acid and metal nanowires.

The conductive composition may further include a chloride ion-containing compound.

The chloride ion-containing compound may include at least one of ammonium chloride, sodium chloride, and potassium chloride.

The acid may be an acid solution having a pH of about 2 to about 6.

The acid may include acetic acid, formic acid, or lactic acid.

The metal nanowires may include silver, copper, platinum, tin, iron, nickel, cobalt, aluminum, zinc, indium, or titanium.

The method of fabricating a transparent conductor may further include forming an overcoating layer on the conductive layer.

The embodiments may be realized by providing an optical display comprising the transparent conductor according to an embodiment.

The optical display may include a display unit; a polarizing plate on the display unit; a transparent electrode structure on the polarizing plate; and a window layer on the transparent electrode structure, wherein the transparent electrode structure includes the transparent conductor.

The optical display may further include another polarizing plate on a side of the display unit that is opposite to the side of the display unit on which polarizing plate, the transparent electrode structure, and the window layer are disposed.

The optical display may include a display unit; a transparent electrode structure on the display unit; a polarizing plate on the transparent electrode structure; and a window layer on the polarizing plate, wherein the transparent electrode structure includes the transparent conductor.

The optical display may further include another polarizing plate on a side of the display unit that is opposite to the side of the display unit on which the transparent electrode structure, the polarizing plate, and the window layer are disposed.

The optical display may include a display unit; and a window layer on the display unit, wherein the display unit includes a transparent electrode structure, the transparent electrode structure including the transparent conductor.

The optical display may further include a polarizing plate on an upper side or a lower side of the display unit.

### BRIEF DESCRIPTION OF THE DRAWINGS

Features will become be to those of skill in the art by describing in detail exemplary embodiments with reference to the attached drawings in which:

FIG. 1 illustrates a cross-sectional view of a transparent conductor according to one embodiment.

FIG. 2 illustrates a cross-sectional view of a transparent conductor according to another embodiment.

FIG. 3 illustrates a cross-sectional view of a transparent conductor according to a further embodiment.

FIG. 4 illustrates a cross-sectional view of a transparent conductor according to yet another embodiment.

FIG. 5 illustrates a cross-sectional view of an optical display according to one embodiment.

FIG. 6 illustrates a cross-sectional view of a display unit according to one embodiment.

FIG. 7 illustrates a cross-sectional view of an optical display according to another embodiment.

FIG. 8 illustrates a cross-sectional view of an optical display according to a further embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. The term “or” is not an exclusive term, e.g., A or B means A, B, or A and B.

In the drawings, portions irrelevant to the description may be omitted for clarity. As used herein, spatially relative terms such as “upper” and “lower” are defined with reference to the accompanying drawings. Thus, it will be understood that the term “upper surface” may be used interchangeably with the term “lower surface”.

As used herein, the “transmittance b* value” refers to a value measured on a transparent conductor, in which a conductive layer (thickness: 20 nm to 200 nm) including metal nanowires and a matrix is stacked on a base film, at a wavelength of 400 nm to 700 nm using a colorimeter CM3600A (Konica Minolta). Here, it should be understood that the embodiments are not limited to a particular material and thickness of the base film, a particular thickness of the conductive layer, a particular wavelength.

As used herein, the “sheet resistance” refers to a value measured on a (non-patterned) surface of a transparent conductor using a non-contact type sheet resistance meter (EC-80P, NAPSON Co., Ltd.).

A transparent conductor according to embodiments may include a base layer and a conductive layer formed on the base layer. The conductive layer may include metal nanowires and a matrix. The transparent conductor may have, e.g., a haze of about 1.2% or less, a total transmittance of about 88% or more and a transmittance b* value of about 1.10 or less at a wavelength of 400 nm to 700 nm. The transparent conductor may have, e.g., a sheet resistance of about 50(Ω/□) or less. The transparent conductor may have, e.g., a sheet resistance change rate of about 10.0% or less, as calculated by Equation 1, below. The transparent conductor may exhibit, e.g., low sheet resistance, good optical properties, and good reliability.

Next, a transparent conductor according to one embodiment will be described with reference to FIG. 1.

Referring to FIG. 1, a transparent conductor 100 according to one embodiment may include a base layer 110 and a conductive layer 120 formed on the base layer 110.

The base layer 110 may be a transparent film and may have a transmittance of about 85% or more, e.g., about 90% or more, at a wavelength of 550 nm. In an implementation, the base layer 110 may have a refractive index of about 1.5 to about 1.65. Within this range, the transparent conductor may have improved optical properties. For example, the base layer 110 may be a film having good flexibility and insulation properties. In an implementation, the base layer 110 may include, e.g., polycarbonate, a cyclic olefin polymer, polyesters including polyethylene terephthalate, polyethylene naphthalate and the like, polyolefin, polysulfone, polyimide, silicone, polystyrene, polyacryl, or polyvinylchloride resins. These may be used alone or in combination thereof. The base layer 110 may be composed of a single layer or multiple layers of two or more resin films. In an implementation, the base layer 110 may have a thickness of about 10 μm to about 200 μm, e.g., about 20 μm to about 150 μm or about 20 μm to about 100 μm. Within this range, the transparent conductor including the base layer may be advantageously used in displays, e.g., in flexible displays.

The conductive layer 120 may be formed on the base layer 110, and may include the metal nanowires 121 and a matrix 122. The conductive layer 120 may include a network formed of the metal nanowires 121 in the matrix to exhibit conductivity, good flexibility, and roundness. The conductive layer 120 may be patterned to form electrodes by etching or other patterning methods and may be used in a flexible device by securing flexibility. In an implementation, the electrodes may be formed in the form of a plurality of lines extending in first and second directions.

The metal nanowires 121 may have better dispersion than metal nanoparticles due to the shape thereof. In addition, the metal nanowires 121 may help achieve significant reduction in sheet resistance of the transparent conductor. The metal nanowires 121 may have an ultra-fine line shape having a particular cross-section. In an implementation, a ratio (L/d, aspect ratio) of a length (L) of the metal nanowires 121 to a cross-sectional diameter (d) of the metal nanowires 121 may be, e.g., about 200 to about 1,250. Within this range, the metal nanowires may help realize a highly conductive network even given a low density of nanowires while reducing sheet resistance of the transparent conductor. In an implementation, the metal nanowires may have an aspect ratio of about 500 to about 1,000, e.g., about 500 to about 700. The metal nanowires 121 may have a cross-sectional diameter (d) of about 100 nm or less. In an implementation, the metal nanowires 121 may have a cross-sectional diameter (d) of about 40 nm to about 100 nm, e.g., about 60 nm to about 100 nm. The metal nanowires 121 may have a length (L) of about 20 μm or more. In an implementation, the metal nanowires 121 may have a length (L) of about 20 μm to about 50 μm. Within these ranges of diameter and length, the metal nanowires 121 may help secure high aspect ratio (L/d), thereby realizing a transparent conductor having high conductivity and low sheet resistance. The metal nanowires 121 may include nanowires prepared from a certain metal. In an implementation, the metal nanowires 121 may include, e.g., silver (Ag), copper (Cu), platinum (Pt), tin (Sn), iron (Fe), nickel (Ni), cobalt (Co), aluminum (Al), zinc (Zn), indium (In), or titanium (Ti). In an implementation, the silver nanowires or a mixture including the silver nanowires may be used as the metal nanowires. The metal nanowires 121 may be prepared by a suitable method or may be a commercially available product. For example, the metal nanowires 121 may be prepared through reduction of a metal salt (e.g., silver nitrate (AgNO₃)) in the presence of a polyol and poly(vinylpyrrolidone). Alternatively, a commercially available product (e.g.: ClearOhm Ink., Cambrios Co., Ltd.) may be used.

The metal nanowires 121 may form a conductive network on the base layer 110. In use, the metal nanowires 121 may be dispersed in a solvent in order to secure easy deposition and adhesion with respect to the base layer 110. Herein, a composition containing the metal nanowires dispersed in a solvent will be referred to as “conductive composition”. The conductive composition may include the metal nanowires and an acid. In an implementation, the metal nanowires 121 may be present in the conductive composition in an amount of about 40 percent by weight (wt %) or more, e.g., about 40 wt % to about 80 wt % or about 50 wt % to about 80 wt %, in terms of sold content. Within this range, the metal nanowires 121 may help form a conductive network so as to secure sufficient conductivity and may exhibit adhesion with respect to the base layer. As used herein, the term “solid content” means the total of remaining components excluding a solvent.

The acid may be an organic acid. In an implementation, the organic acid may include, e.g., acetic acid, formic acid, or lactic acid. In an implementation, the acid may be acetic acid. According to the embodiment, the acid may help remove various impurities from the metal nanowires such that the transparent conductor may exhibit the same or improved optical properties (haze, transmittance and transmittance b* value) at low resistance, as compared with those at high resistance. In an implementation, the acid may be present in the conductive composition in an amount of about 0.01 wt % to about 10.0 wt %, e.g., about 0.01 wt % to about 5 wt %, in terms of sold content. Within this range of the acid, the transparent conductor may exhibit low resistance and good optical properties. The acid may be an acid solution having a pH of about 2 to about 6. In an implementation, the acid may be added in the form of an acid solution to the conductive composition. In an implementation, about 1 wt % to about 3 wt % of the acid solution (e.g., the acid aqueous solution) may be added to the conductive composition.

The conductive composition may further include a chloride, e.g., a chloride ion-containing compound. The chloride ion-containing compound may include, e.g., ammonium chloride (NH₄Cl), sodium chloride (NaCl), or potassium chloride (KCl). In an implementation, ammonium chloride may be used. According to the embodiment, the chloride ion-containing compound may help suppress an increase in contact resistance that could otherwise be caused by oxidation of the metal nanowires in a remaining acid or moisture, thereby securing good reliability. In an implementation, the chloride ion-containing compound may be present in the conductive composition in an amount of about 1×10⁻⁷ wt % to about 1.0 wt % in terms of sold content. In an implementation, the chloride ion-containing compound may be present in an amount of about 1×10⁻⁷ wt % to about 0.01 wt %, e.g., about 1×10⁻⁷ wt % to about 0.001 wt %. Within this range of the chloride ion-containing compound, the transparent conductor may help secure low resistance, good optical properties, and good reliability. In an implementation, the chloride ion-containing compound may be added in the form of a chloride aqueous solution to the conductive composition. In an implementation, about 0.01 wt % to about 0.1 wt % of the chloride aqueous solution may be added to the conductive composition.

The conductive composition may further include a solvent. The solvent may include water or an organic solvent. In an implementation, water may be used with a view toward eco-friendly preparation. In an implementation, deionized water may be used.

The conductive composition may include, e.g., an additive and/or a binder in order to help secure or facilitate dispersion of the metal nanowires. In an implementation, the binder may include a suitable binder, e.g., carboxy methyl cellulose (CMC), 2-hydroxy ethyl cellulose (HEC), hydroxy propyl methyl cellulose (HPMC), methyl cellulose (MC), polyvinyl alcohol (PVA), tripropylene glycol (TPG), polyvinylpyrrolidone, xanthan gum (XG), alkoxylates including ethoxylates, ethylene oxide, propylene oxide, or the like. These may be used alone or as a mixture or copolymer thereof. In an implementation, the additive and the binder may be present in a balance amount in the conductive composition in terms of sold content.

The matrix 122 may be impregnated with the metal nanowires 121. For example, the metal nanowires may be dispersed or embedded in the matrix 122. Some metal nanowires 121 may be exposed from the matrix 122. The matrix 122 may help reduce the possibility of and/or prevent oxidation or abrasion of the metal nanowires 121 (which may be exposed from an upper surface of the conductive layer 120) may help significantly reduce transmittance of corrosive components under corrosive environments (e.g., moisture, a trace of acid, oxygen, sulfur, and the like), may help provide adhesion between the conductive layer 120 and the base layer 110, and/or may help improve optical properties, chemical resistance, and solvent resistance of the transparent conductive film.

The matrix 122 may be formed of a composition including, e.g., a binder and an initiator. In an implementation, the binder may include, e.g., at least one polyfunctional monomer. In an implementation, the matrix 122 may be formed of a matrix composition including a penta- or higher functional monomer including, e.g., a penta- or hexa-functional monomer, and a tri-functional monomer. The penta- or higher functional monomer and the tri-functional monomer may be (meth)acrylate-based monomers having (meth)acrylate groups, and may be non-urethane-based monomers free from a urethane group. The matrix composition including the non-urethane-based monomer may facilitate dense stacking cured products in the network structure of the metal nanowires 121 and may help improve adhesion of the metal nanowires to the base layer 110. In an implementation, the penta- or hexa-functional monomer may be, e.g., a penta- or hexa-functional monomer of a C₃ to C₂₀ polyhydric alcohol. In an implementation, the penta- or hexa-functional monomer may include, e.g., dipentaerythritol penta(meth)acrylate, dipentaerythritol hexa(meth)acrylate, caprolactone-modified dipentaerythritol penta(meth)acrylate, or caprolactone-modified dipentaerythritol hexa(meth)acrylate. In an implementation, the penta- or higher functional monomer may be present in an amount of about 30 to about 60 parts by weight, e.g., about 30 parts by weight to about 50 parts by weight or about 30 parts by weight to about 50 parts by weight, relative to 100 parts by weight of the matrix composition in terms of solid content. Within this range of the penta- or higher functional monomer, the matrix composition may help maintain reliability and conductivity of the transparent conductor. Herein, the term “solid content” of the matrix composition means the total of remaining components of the matrix composition excluding a solvent.

The tri-functional monomer may include, e.g., a tri-functional monomer of a C₃ to C₂₀ polyhydric alcohol or an alkoxy group-modified tri-functional monomer of a C₃ to C₂₀ polyhydric alcohol. In an implementation, the tri-functional monomer may include, e.g., trimethylolpropane tri(meth)acrylate, glycerol tri(meth)acrylate, pentaerythritol tri(meth)acrylate, or dipentaerythritol tri(meth)acrylate. The alkoxy group-modified tri-functional monomer of the C₃ to C₂₀ polyhydric alcohol may help further improve transmittance and reliability of the transparent conductor while reducing the transmittance b* value thereof to help reduce and/or prevent the conductive layer from exhibiting a yellow color due to color distortion, as compared with the tri-functional monomer free from an alkoxy group. In an implementation, the tri-functional monomer having an alkoxy group (e.g., a C₁ to C₅ alkoxy group) may include, e.g., ethoxylated trimethylolpropane tri(meth)acrylate or propoxylated glyceryl tri(meth)acrylate. In an implementation, the tri-functional monomer may be present in an amount of about 5 parts by weight to about 20 parts by weight, e.g., about 5 parts by weight to about 15 parts by weight, relative to 100 parts by weight of the matrix composition in terms of solid content. Within this range of the tri-functional monomer, the matrix composition may help maintain reliability and conductivity of the transparent conductor.

The matrix composition may include the initiator. The initiator may be a suitable photo initiator, e.g., a photo radical initiator. In an implementation, the initiator may be an α-hydroxy ketone initiator, e.g., 1-hydroxycyclohexylphenylketone or a mixture including the same. In an implementation, the initiator may be present in an amount of about 1 part by weight to about 15 parts by weight, e.g., about 2 parts by weight to about 10 parts by weight, relative to 100 parts by weight of the matrix composition in terms of solid content.

The matrix composition may further include an adhesion enhancer. The adhesion enhancer may help enhance adhesion of the metal nanowires 121 to the base layer 110 while improving reliability of the transparent conductor 100. In an implementation, the adhesion enhancer may include, e.g., a silane coupling agent, a mono-functional monomer, a di-functional monomer, or a tri-functional monomer. The silane coupling agent may be a suitable silane coupling agent. For example, a silane coupling agent including amino group or epoxy group may be used. With the silane coupling agent, the composition may help improve adhesion and chemical resistance of the transparent conductor. In an implementation, the silane coupling agent may include, e.g., a silicon compound having an epoxy structure, such as 3-glycidoxypropyltrimethoxysilane, 3-glycidoxypropylmethyldimethoxysilane, and 2-(3,4-epoxycyclohexyl)ethyltrimethoxysilane; a silicon compound having a polymeric unsaturated group, such as vinyltrimethoxysilane, vinyltriethoxysilane, and (meth)acryloxypropyltrimethoxysilane; a silicon compound having an amino group, such as 3-aminopropyltrimethoxysilane, 3-aminopropyltriethoxysilane, N-(2-aminoethyl)-3-aminopropyltrimethoxysilane, and N-(2-aminoethyl)-3-aminopropylmethyldimethoxysilane; or 3-chloropropyltrimethoxysilane. As the mono-functional to tri-functional monomer, an acid ester monomer may be used. In an implementation, the mono-functional to tri-functional monomer may include a mono- to tri-functional (meth)acrylate monomer having a (meth)acrylate group, e.g., a mono- to tri-functional monomer of a C₃ to C₂₀ polyhydric alcohol or at least one of isobornyl(meth)acrylate, cyclopentyl(meth)acrylate, cyclohexyl(meth)acrylate, trimethylolpropane di(meth)acrylate, ethyleneglycol di(meth)acrylate, neopentylglycol di(meth)acrylate, hexanediol di(meth)acrylate, and cyclodecane dimethanol di(meth)acrylate. In an implementation, the adhesion enhancer may be present in an amount of about 1 part by weight to about 15 parts by weight, e.g., about 5 parts by weight to about 10 parts by weight, relative to 100 parts by weight of the matrix composition. Within this range, the matrix composition may help improve adhesion of the metal nanowires while maintaining reliability and conductivity of the transparent conductor.

The matrix composition may further include an antioxidant. The antioxidant may help reduce the possibility of and/or prevent oxidation of the metal nanowire network of the conductive layer 120. In an implementation, the antioxidant may include, e.g., a triazole-based antioxidant, a triazine-based antioxidant, a phosphorus-based antioxidant such as a phosphite-based antioxidant, a hindered amine light stabilizer (HALS)-based antioxidant, or a phenol-based antioxidant. For example, a mixture of these antioxidants may be used in order to help improve reliability of the transparent conductor while preventing oxidation of the metal nanowires 121. Use of two or more antioxidants may provide further improved effects in terms of anti-oxidation and reliability. In an implementation, the antioxidant may be a mixture of the phosphorus-based antioxidant and the phenol-based antioxidant, a mixture of the phosphorus-based antioxidant and the HALS-based antioxidant, or a mixture of the phenol-based antioxidant and the HALS-based antioxidant, particularly, a mixture of the phosphorus-based antioxidant and the HALS-based antioxidant, a mixture of the triazole-based antioxidant, the phenol-based antioxidant and the phosphorus-based antioxidant, or a mixture of the triazine-based antioxidant, the phenol-based antioxidant and the phosphorus-based antioxidant. In the transparent conductor 100, the phosphorus-based antioxidant may help reduce the transmittance b* value of the transparent conductor without deteriorating conductivity of the conductive layer 120. In an implementation, the phosphorus-based antioxidant may include tris(2,4-di-tert-butylphenyl)phosphite and the phenol-based antioxidant may include pentaerythritol tetrakis(3-(3,5-di-tert-butyl-4-hydroxyphenyl)propionate). The HALS-based antioxidant may include, e.g., bis(2,2,6,6-tetramethyl-4-piperidyl)sebacate, bis(2,2,6,6-tetramethyl-4-piperidinyl)sebacate, bis(2,2,6,6-tetramethyl-5-piperidinyl)sebacate, a copolymer of dimethyl succinate and 4-hydroxy-2,2,6,6-tetramethyl-1-piperidine ethanol), or 2,4-bis[N-butyl-n-(1-cyclohexyloxy-2,2,6,6-tetramethylpiperidine-4-yl)amino]-6-(2-hydroxyethylamine)-1,3,5-triazine. In an implementation, the antioxidant may be present in an amount of about 0.1 parts by weight to about 5 parts by weight, e.g., about 0.5 parts by weight to about 2 parts by weight, relative to 100 parts by weight of the matrix composition. Within this range, the matrix composition may help reduce and/or prevent oxidation of the metal nanowire network while reducing the transmittance b* value.

In an implementation, the matrix composition may further include nanoparticles. The nanoparticles may help reduce haze of the transparent conductor while improving transmittance. The nanoparticles may be inorganic nanoparticles, e.g., silica (SiO₂), titanium dioxide (TiO₂), zirconium oxide (ZrO₂), aluminum oxide (Al₂O₃), zinc oxide (ZnO), indium oxide (In₂O₃), tin oxide (SnO₂), antimony oxide (Sb₂O), indium tin oxide (ITO), antimony tin oxide (ATO), or the like. ITO or ATO may additionally impart an antistatic function to the matrix composition. The inorganic nanoparticles may have a hollow structure. The inorganic nanoparticles having a hollow structure may have a refractive index of about 1.4 or less, e.g., about 1.33 to about 1.38. For example, hollow silica may be used. The inorganic nanoparticles having a hollow structure may include hollow nanoparticles not subjected to surface treatment, or surface-treated hollow nanoparticles subjected to surface treatment with a curable functional group (for example, a (meth)acrylate group), a dispersant, or a coupling agent. The surface-treated hollow nanoparticles may help improve durability of the matrix and the transparent conductive layer and may be more firmly coupled to the base layer or uniformly dispersed in the binder through curing reaction with the binder of the matrix composition. In an implementation, the surface-treated hollow nanoparticles may be prepared by surface treating, e.g., about 10% to about 80% of an overall outer surface area of the hollow nanoparticles, about 20% to about 70%, or about 40% to about 60%, with a (meth)acrylate compound. Within this range, the hollow nanoparticles may exhibit good reactivity with the binder to improve durability of the transparent conductive layer and can be more firmly coupled to the base layer. The hollow nanoparticles subjected to surface treatment with the (meth)acrylate compound may be prepared by a suitable method or may be a commercially available product. The surface-treated hollow nanoparticles may be prepared by, e.g., coating the surfaces of hollow silica particles with a silane group-containing compound, followed by addition reaction with the (meth)acrylate compound.

The nanoparticles may have an average particle size (D50) of about 30 nm to about 100 nm, e.g., about 40 nm to about 70 nm. Within this range, the nanoparticles may help further improve optical properties of the transparent conductor, such as haze and transmittance. In an implementation, the nanoparticles may be present in an amount of about 20 parts by weight to about 60 parts by weight, e.g., about 30 parts by weight to about 50 parts by weight, relative to 100 parts by weight of the matrix composition. Within this range, the nanoparticles may help further improve optical properties of the transparent conductor, such as haze and transmittance.

The matrix composition may further include, e.g., additives for improvement of performance, such as a thickening agent, a dispersant, or a UV stabilizer.

In an implementation, the conductive layer 120 may have a thickness of about 10 nm to about 1 μm, e.g., about 20 nm to about 200 nm, about 30 nm to about 130 nm, or about 50 nm to about 100 nm. Within this thickness range, the transparent conductor 100 may be applied to films for touch panels. Within this thickness range, the transparent conductor 100 may have low contact resistance, improved durability and chemical resistance, and good optical properties.

In an implementation, the transparent conductor 100 may further include a functional layer stacked on one or both surfaces of the base layer 110. The functional layer may include, e.g., a hard coating layer, an anti-corrosion layer, an anti-reflection layer, an anti-glare layer, an adhesion enhancing layer, and a barrier layer.

The hard coating layer or the anti-corrosion layer refers to a coating for protecting a surface of a target layer from scratches or corrosion. The hard coating layer may include synthesized polymers such as epoxy, polyurethane, polysilane, or the like. In an implementation, the hard coating layer may include colloidal silica. In an implementation, the hard coating layer may have a thickness of about 1 μm to about 50 μm. Hardness of the hard coating layer may be evaluated by a suitable method, e.g., by reciprocating steel wool on the coating layer 50 times within a distance of 2 cm under conditions of twice per second at a speed of 300 g/cm². The hard coating layer may be additionally exposed to an anti-reflection process or anti-glare process known in the art.

The anti-reflection layer refers to a layer capable of reducing reflection loss on the surface of the transparent conductor. Thus, the anti-reflection layer may be placed on an outer surface of the transparent conductor or may be interposed between layers. The anti-reflection layer may be formed of suitable materials including, e.g., fluorine polymers or mixtures or copolymers thereof. Reflection loss may be efficiently reduced by controlling the thickness of the anti-reflection layer.

The anti-glare layer refers to a layer for reducing reflection on the outer surface of the transparent conductor by providing fine roughness to the surface of the transparent conductor in order to scatter light. Suitable anti-glare materials may include, e.g., siloxane, a polystyrene/PMMA mixture, lacquer (for example, butyl acetate/nitrocellulose/wax/alkyd resin), polythiophenes, polypyrroles, polyurethane, nitrocellulose, and acrylates. These materials may include a light spreading material such as a colloid or fumed silica. Mixtures and copolymers of these materials may facilitate heterogeneous properties between micrometer scale components and can provide a light spreading function in order to reduce glare.

The adhesion enhancing layer refers to an optically transparent layer for coupling two adjacent layers (e.g., the conductive layer and the substrate) without affecting physical, electrical, or optical properties of each layer. A suitable optically transparent material may be used. Examples of the optically transparent material may include acrylic resins, chlorinated olefin resins, maleic acid resins, chlorinated rubber resins, cyclic rubber resins, polyamide resins, cumarone indene resins, ethylene-vinyl acetate copolymers, polyester resins, urethane resins, and polysiloxane.

The barrier layer refers to a layer for reducing or blocking permeation of gas or fluids into the transparent conductor. Permeation of gas or fluids into the transparent conductor could cause significant deterioration not only in light transmittance of the conductive layer but also in electrical conductivity of the transparent conductor. The barrier layer may help effectively reduce and/or prevent a corrosive gas from entering the conductive layer and from contacting the metal nanowires in the matrix. In an implementation, any one of the anti-reflection layer, the anti-glare layer and the hard coating layer may act as the barrier layer.

The transparent conductor 100 may be transparent in the visible range, e.g., at a wavelength of about 400 nm to about 700 nm. In an implementation, the transparent conductor 100 may have a haze of about 1.2% or less, e.g., about 0.5% to about 1.2% or about 0.7% to about 1.1%, as measured at a wavelength of about 400 nm to about 700 nm using a haze meter. In an implementation, the transparent conductor 100 may have a total transmittance of about 88% or more, e.g., about 90% or more or about 90% to about 99%, as measured at a wavelength of about 400 nm to about 700 nm using a haze meter. Within this range, the transparent conductor 100 may exhibit high transmittance, good transparency, and low resistance change rate, and may be used as a film for transparent electrodes through patterning of the transparent conductor 100.

In an implementation, the transparent conductor 100 may have a transmittance b* value of about 1.10 or less, e.g., about 0.5 to about 1.10 or about 0.8 to about 1.10, at a wavelength of about 400 nm to about 700 nm. Within this range, the transparent conductor 100 may exhibit high transmittance and low resistance change rate, and may be used as a transparent electrode film through patterning of the transparent conductor 100. The matrix 122 may help provide durability, chemical resistance, and solvent resistance (usually associated with transparent conductors) to the transparent conductor 100.

In an implementation, the transparent conductor 100 may have a sheet resistance of about 50Ω/□ or less, e.g., about 40Ω/□ or less or about 25Ω/□ to about 40Ω/□, as measured by a non-contact type sheet resistance meter (EC80P, NAPPON Co., Ltd.). Within this range, the transparent conductor 100 may have low sheet resistance to be used as a film for transparent electrodes and may be applied to a large touch panel.

In an implementation, the transparent conductor 100 may have a sheet resistance change rate of about 10.0% or less, e.g., about 3% to about 10.0%, as calculated by the following Equation 1. Within this range, the transparent conductor 100 may help suppress increase in contact resistance, which could otherwise occur due to a remaining acid or moisture in the metal nanowires, thereby providing good reliability. The sheet resistance change rate may be evaluated by measuring initial sheet resistance (a) (unit: Ω/□) using a non-contact type sheet resistance meter (EC80P, NAPPON Co., Ltd.), followed by measuring sheet resistance (b) (unit: Ω/□) using the same method after leaving the transparent conductor under conditions of 85° C. and 85% RH (relative humidity) for 240 hours:

Sheet resistance change rate=|b−a|/a×100 [Equation 1]

In Equation 1, a is initial sheet resistance of the transparent conductor and b is sheet resistance of the transparent conductor after being left under conditions of 85° C. and 85% relative humidity for 240 hours.

The conductive layer including the metal nanowires and the matrix may be formed on an upper surface of the base layer in the transparent conductor according to the embodiment shown in FIG. 1. In an implementation, the conductive layer including the metal nanowires and the matrix may be also formed on a lower surface of the base layer (e.g., an opposite surface relative to the upper surface) in transparent conductors according to other embodiments.

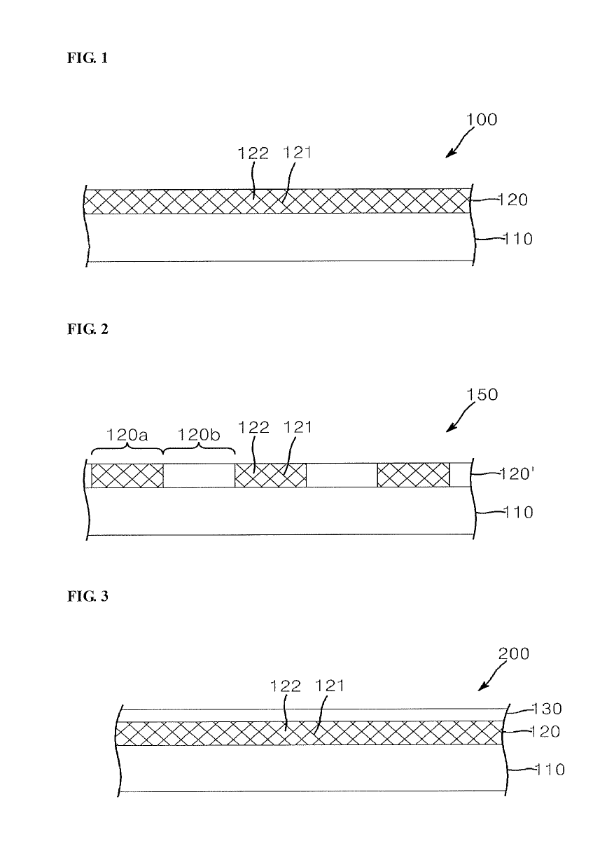

Next, a transparent conductor according to another embodiment will be described with reference to FIG. 2.

Referring to FIG. 2, a transparent conductor 150 according to another embodiment may include, e.g., a base layer 110 and a patterned conductive layer 120′. The patterned conductive layer 120′ may include a metal nanowire-containing conductive layer 120a formed on an upper surface of the base layer 110 and including metal nanowires 121 and matrix 122, and a metal nanowire-free layer 120b composed of a matrix and not including metal nanowire. The transparent conductor 150 according to this embodiment is substantially the same as the transparent conductor 100 according to the above embodiment except that the conductive layer 120′ is subjected to patterning.

The conductive layer 120′ may be subjected to patterning by a predetermined method, e.g., etching with an acid solution. With the structure wherein the conductive layer 120′ is patterned, the transparent conductor may be used as a conductor by forming x and y channels. Upon etching, an etchant may be an acid etchant having a pH of about 2 to about 5 and etching may be performed at about 30° C. to about 45° C. Within this range, the conductive layer may be subjected to etching to have a line width required for the transparent conductor. The etchant may be an aqueous solution containing at least one of phosphoric acid, nitric acid, and acetic acid. For example, the etchant may be an aqueous solution containing about 75 wt % to about 85 wt % (about 85 vol %) of phosphoric acid, about 3 wt % to about 5 wt % (about 70 vol %) of nitric acid, about 1 wt % to about 10 wt % (99.7 vol %) of acetic acid, and the balance of water. Within this range, the conductive layer may be subjected to etching to have a line width required for the transparent conductor. For example, as shown in FIG. 2, the metal nanowire-containing conductive layer 120a may contain the metal nanowires since the metal nanowires are not subjected to etching, and the metal nanowire-free layer 120b may be composed of the matrix alone since the metal nanowires are subjected to etching.

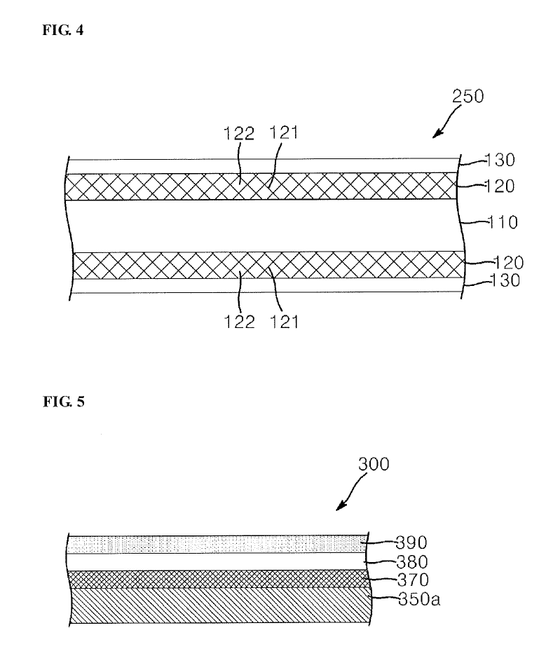

Next, transparent conductors according to other embodiments will be described with reference to FIG. 3 and FIG. 4.

Referring to FIG. 3, a transparent conductor 200 may include, e.g., a base layer 110, a conductive layer 120 formed on an upper surface of the base layer 110 and including metal nanowires 121 and a matrix 122, and an overcoating layer 130 formed on an upper surface of the conductive layer 120. The overcoating layer 130 of the transparent conductor may help reduce and/or prevent oxidation of the metal nanowires 121 in the conductive layer 120 while improving adhesion between the conductive layer 120 and the base layer 110. In an implementation, the transparent conductive layer and the overcoating layer may be formed on the upper surface of the base layer in the embodiment as shown in FIG. 3. In an implementation, a conductive layer, or a transparent conductive layer and an overcoating layer may be further formed on a lower surface of the base layer, as shown in FIG. 4. The transparent conductor 200 according to this embodiment is substantially the same as the transparent conductor according to the above embodiment except that the overcoating layer 130 is further formed. Thus, the overcoating layer 130 will be mainly described hereinafter.

In an implementation, the conductive layer 120 may be integrally formed with the overcoating layer 130. As used herein, “integrally formed with” means that the conductive layer 120 and the overcoating layer 130 are neither bonded to each other via a bonding layer or the like, nor independently separated from each other.

The overcoating layer 130 may be formed by coating an overcoating composition, which may be prepared by, e.g., dissolving a thermosetting or radiation curable resin, a curing initiator, and a curing agent in a solvent, on the base layer, followed by heat and/or radiation curing. The thermosetting or radiation curable resin may include, e.g., a compound having two or more curable functional groups. For example, the two or more curable functional groups may include an unsaturated double bond such as (meth)acrylates, and a reactive substituent group such as an epoxy group or a silanol group. Examples of the compound having two or more curable functional groups may include ethyleneglycol di(meth)acrylate, neopentylglycol di(meth)acrylate, 1,6-hexanediol di(meth)acrylate, trimethylolpropane tri(meth)acrylate, dipentaerythritol hexa(meth)acrylate, polyol poly(meth)acrylate, di(meth)acrylate of bisphenol A-diglycidyl ether; and polyester (meth)acrylate, urethane (meth)acrylate, pentaerythritol tetra(meth)acrylate, and glyceryl tri(meth)acrylate as obtained through esterification of polyhydric alcohols, polyhydric carboxylic acid, or anhydrides and acrylic acid thereof. In an implementation, a fluorine-containing epoxy acrylate or a fluorine-containing alkoxysilane may be used as the compound having two or more curable functional groups. For example, 2-(perfluorodecyl)ethyl (meth)acrylate, 3-perfluorootyl-2-hydroxypropyl (meth)acrylate, 3-(perfluroro-9-mehtyldecyl)-1,2-epoxy propane, ethyl (meth)acrylate-2,2,2-trifluoroethyl, or (meth)acrylate-2-trifluoromethyl-3,3,3-trifluoropropyl may be used. These compounds may be used alone or as a mixture thereof.

The curing initiator may help curing of the coating solution. Examples of the curing initiator may include benzoin, benzoin methyl ether, acyl phosphine oxide compounds, peroxide compounds such as benzoin peroxide and butyl peroxide, benzoin compounds such as isopropyl thioxanthone and benzoin isopropyl ether, carbonyl compounds such as benzyl, benzophenone and acetophenone, azo compounds such as azobisisobutyronitrile and azodibenzoyl, a mixture of diketone and tertiary amine, a cationic photo-initiator, anhydrides, peroxides, α-hydroxy alkylphenones, α,α-dialkoxyacetophenone, α-hydroxy alkylphenones, α-aminoalkylphenone derivatives, α-hydroxy alkylphenone polymers, thioxanthone derivatives, water-soluble aromatic ketones, and titanocene compounds. In an implementation, the curing initiator may be present in an amount of 0.1 to 20 parts by weight relative to 100 parts by weight of the thermosetting or radiation curable resin in terms of solid content. Examples of the solvent for the overcoating composition may include alcohols such as methyl alcohol, ethyl alcohol, isopropyl alcohol, and propanol; ketones such as methyl isobutyl ketone and methyl ethyl ketone; esters such as methyl acetate and ethyl acetate; aromatic compounds such as toluene, xylene, and benzene; and ethers such as dimethyl ether.

In an implementation, in addition to the aforementioned organic compounds, the overcoating composition may further include inorganic nanoparticles in order to adjust an index of refraction, surface tension, and hardness. Examples of the inorganic nanoparticles may include silica (SiO₂), titanium dioxide (TiO₂), zirconium oxide (ZrO₂), aluminum oxide (Al₂O₃), zinc oxide (ZnO), indium oxide (In₂O₃), tin oxide (SnO₂), antimony oxide (Sb₂O), indium tin oxide (ITO), antimony tin oxide (ATO), and the like. ITO or ATO may additionally impart an antistatic function to the overcoating composition.

In an implementation, the overcoating composition may further include additives for improvement of performance, e.g. an adhesion enhancer and an antioxidant. In an implementation, the additives may be present in an amount of 0.01 wt % to 10 wt % in the overcoating composition in terms of solid content.

In an implementation, the overcoating layer 130 may have a thickness of about 20 nm to about 200 nm, e.g., about 30 nm to about 130 nm or about 50 nm to about 100 nm. Within this thickness range, the overcoating layer 130 may help reduce and/or prevent oxidation of the metal nanowires while improving adhesion between the conductive layer and the base layer.

In an implementation, the transparent conductors 100, 150, 200, 250 may have a thickness of about 10 μm to about 250 μm, e.g., about 10 μm to about 130 μm. Within this range, the transparent conductors may be used as a transparent electrode film including a film for touch panels, and may be used as a transparent electrode film for flexible touch panels. The transparent conductor may be used in film form as a transparent electrode film of touch panels, e-paper, and solar cells through patterning by etching and the like.

Next, a method of fabricating a transparent conductor according to one embodiment will be described.

The method of fabricating a transparent conductor according to one embodiment may includes, e.g., forming a metal nanowire network on a base layer and forming a conductive layer on the metal nanowire network, wherein the conductive composition includes metal nanowires and an acid. The conductive composition may further include a chloride, e.g., a chloride ion-containing compound. The fabrication method according to the embodiment may provide a transparent conductor having good properties in terms of conductivity, optical properties, chemical resistance, and reliability.

First, the metal nanowire network may be formed on the base layer.

For example, the metal nanowire network may be formed by depositing the conductive composition on the base layer, followed by drying. In order to facilitate deposition of the conductive composition on the base layer and secure adhesion of the conductive composition to the base layer, the conductive composition may include metal nanowires dispersed in a liquid. For example, the conductive composition may include metal nanowires and an acid. The conductive composition may further include a chloride ion-containing compound. Details of the conductive composition are the same as those described in the transparent conductor 100 according to the above embodiment. A method of coating the conductive composition onto the base layer may include, e.g., bar coating, spin coating, dip coating, roll coating, flow coating, and die coating. After coating the conductive composition onto the base layer, a metal nanowire network may be formed on the base layer by drying the conductive composition. Drying may be performed, e.g., at about 80° C. to about 140° C. for about 1 minute to about 30 minutes.

Thereafter, a conductive layer may be formed on or from the metal nanowire network.

For example, a conductive layer may be formed on or from the metal nanowire network by depositing a matrix composition onto the metal nanowire network, followed by curing.

Details of the matrix composition are the same as those described in the transparent conductor 100 according to the above embodiment. A method of coating the matrix composition onto the metal nanowire network may include, e.g., bar coating, spin coating, dip coating, roll coating, flow coating, and die coating. The metal nanowire network may be formed by coating the metal nanowire composition onto the base layer, followed by drying, and the matrix composition coated onto the metal nanowire network may permeate into the metal nanowire network. As a result, metal nanowires may be impregnated in the matrix composition, thereby forming a conductive layer including the metal nanowires and the matrix. The metal nanowires may be completely impregnated in the matrix, or may be partially exposed from the surface of the conductive layer. After coating the matrix composition, the matrix composition may be subjected to drying. For example, the coated matrix composition may be dried at 80° C. to 120° C. for 1 minute to 30 minutes.

Thereafter, at least one of photocuring and thermo-curing may be carried out. Photocuring may be performed through irradiation at a dose of 300 mJ/cm² to 1,000 mJ/cm² at a wavelength of 400 nm or less. Thermo-curing may be performed at 50° C. to 200° C. for 1 hour to 120 hours

Next, a method of fabricating a transparent conductor according to another embodiment will be described. The method according to this embodiment is substantially the same as the method according to the above embodiment except that the method according to this embodiment further includes forming an overcoating layer on the conductive layer. The following description will focus on formation of the overcoating layer.

In a process of forming the overcoating layer, an overcoating composition is deposited on the conductive layer, followed by curing.

Details of the overcoating composition are the same as those described in the transparent conductor 200 according to the above embodiment. A method of coating the overcoating composition onto the conductive layer may include, e.g., bar coating, spin coating, dip coating, roll coating, flow coating, and die coating. In an implementation, the overcoating composition may be coated to a thickness of about 20 nm to about 200 nm, e.g., about 30 nm to about 130 nm or about 50 nm to about 100 nm. Within this thickness range, the overcoating layer may help reduce and/or prevent oxidation of the metal nanowires while improving adhesion between the conductive layer and the base layer.

After coating the overcoating composition, the overcoating composition may be subjected to drying at 60° C. to 150° C. for 1 minute to 30 minutes.

Thereafter, the overcoating composition may be subjected to photocuring through irradiation at a dose of 300 mJ/cm² to 1,000 mJ/cm² at a wavelength of 400 nm or less.

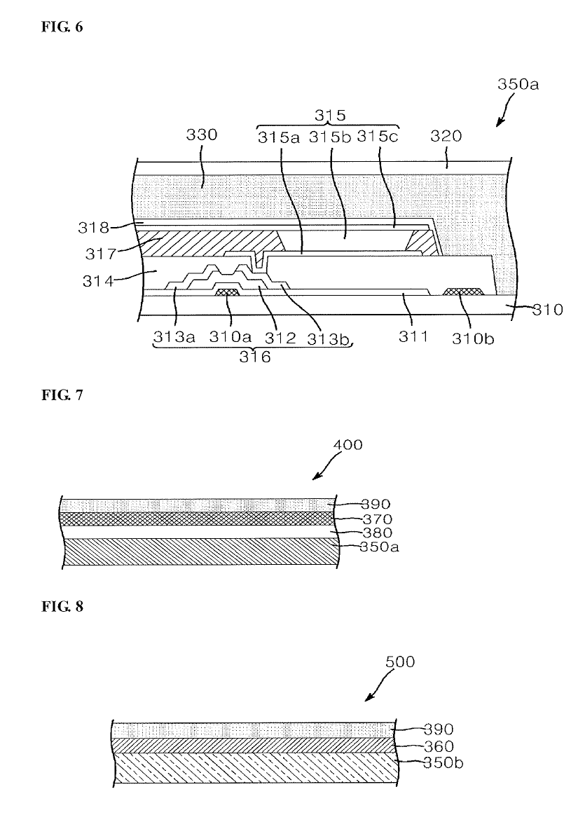

Next, an optical display according to one embodiment will be described with reference to FIG. 5 to FIG. 6. FIG. 5 illustrates a sectional view of an optical display according to one embodiment and FIG. 6 illustrates a sectional view of one embodiment of a display unit shown in FIG. 5. The optical display according to the embodiment may include the transparent conductor according to the embodiments. In an implementation, the optical display may include, e.g., optical displays including touch panels, touchscreen panels, and flexible displays; e-paper; and solar cells.

Referring to FIG. 5, an optical display 300 according to one embodiment may include, e.g., a display unit 350a, a polarizing plate 370 formed on the display unit 350a, a transparent electrode structure 380 formed on the polarizing plate 370, and a window layer 390 formed on the transparent electrode structure 380. The transparent electrode structure 380 may include the transparent conductor according to the embodiments described above.

The display unit 350a may drive the optical display 300, and may include a substrate and an optical device including an OLED, an LED, or an LCD formed on the substrate. Referring to FIG. 6, the display unit 350a may include a lower substrate 310, a thin film transistor 316, an organic light emitting diode 315, a planarization layer 314, a protective layer 318, an insulation layer 317, a bonding layer 330, and an upper substrate 320.

The lower substrate 310 may support the display unit 350a and may be bonded to the upper substrate 320 so as to face each other through the bonding layer 330. The thin film transistor 316 and the organic light emitting diode 315 may be formed on the lower substrate 310. The lower substrate 310 may also be provided with a flexible printed circuit board (FPCB) for driving the transparent electrode structure 380. The flexible printed circuit board may be further provided with a timing controller for driving an array of organic light emitting diodes, a power supply, or the like.

The lower substrate 310 may include a substrate formed of a flexible resin. For example, the lower substrate 310 may include a flexible substrate such as a silicon substrate, a polyimide substrate, a polycarbonate substrate, or a polyacrylate substrate.

In a display area of the lower substrate 310, plural pixel domains are defined by plural driving wires and plural sensor wires intersecting each other and each of the pixel domains may be formed with an array of organic light emitting diodes, each of which includes the thin film transistor 316 and the organic light emitting diode 315 connected to the thin film transistor 316. In a non-display area of the lower substrate 310, a gate driver applying electric signals to the driving wires may be formed in the form of a gate-in panel. The gate-in panel unit may be formed on one or both sides of the display area.

The thin film transistor 316 may control electric current flowing through a semiconductor by application of an electric field perpendicular to the electric current and may be formed on the lower substrate 310. The thin film transistor 316 may include a gate electrode 310a, a gate insulation layer 311, a semiconductor layer 312, a source electrode 313a, and a drain electrode 313b. The thin film transistor 316 may be an oxide thin film transistor which uses an oxide such as indium gallium zinc oxide (IGZO), ZnO, and TiO as the semiconductor layer 312, an organic thin film transistor which uses an organic material as the semiconductor layer, an amorphous silicon thin film transistor which uses amorphous silicon as the semiconductor layer, or a polycrystalline silicon thin film transistor which uses polycrystalline silicon as the semiconductor layer.

The planarization layer 314 covers the thin film transistor 316 and a circuit section 310b to flatten upper surfaces of the thin film transistor 316 and the circuit section 310b such that the organic light emitting diode 315 can be formed thereon. The planarization layer 314 may be formed of a spin-on-glass (SOG) film, a polyimide polymer, or a polyacrylic polymer.

The organic light emitting diode 315 realizes a display through self-emission and may be formed on the planarization layer 314. The organic light emitting diode 315 may include a first electrode 315a, an organic light-emitting layer 315b, and a second electrode 315c, which are stacked in the stated order. Adjacent organic light emitting diodes may be isolated from each other by the insulation layer 317. The organic light emitting diode 315 may have a bottom emission type structure wherein light generated from the organic light-emitting layer 315b is emitted through the lower substrate, or a top-emission type structure wherein light from the organic light-emitting layer 315b is emitted through the upper substrate.

The protective layer 318 covers the organic light emitting diode 315 to protect the organic light emitting diode 315. The protective layer 318 may be formed of an inorganic insulation material such as SiOx, SiNx, SiC, SiON, SiONC, and amorphous carbon (a-C), or an organic insulation material such as acrylate, epoxy polymers, imide polymers, and the like.

The bonding layer 330 bonds the lower substrate 310 including the protective layer 318 to the upper substrate 320 such that the upper and lower substrates face each other. The bonding layer 330 may be formed of a UV curable resin or heat curable resin such as a (meth)acrylic resin, epoxy resin, and urethane resin. The bonding layer 330 may further include a moisture or oxygen absorbent to protect the organic light emitting diode.

The upper substrate 320 protects the organic light emitting diode 315 and the thin film transistor 316, and may be formed of the same or different materials from that of the lower substrate 310. For example, the upper substrate 320 may include a flexible substrate such as a silicon substrate, a polyimide substrate, a polycarbonate substrate, and a polyacrylate substrate.

Referring to FIG. 5 again, the polarizing plate 370 may realize polarization of internal light or prevent reflection of external light to realize a display, or may help increase contrast of the display. In an implementation, the polarizing plate 370 may be composed of a polarizer alone. In an implementation, the polarizing plate 370 may include a polarizer and a protective film formed on one or both surfaces of the polarizer. In an implementation, the polarizing plate 370 may include a polarizer and a protective coating layer formed on one or both surfaces of the polarizer. As the polarizer, the protective film, and the protective coating layer, a suitable polarizer, a suitable protective film and a suitable protective coating layer may be used.

The transparent electrode structure 380 may generate electrical signals through detection of variation in capacitance when a human body or a conductor such as a stylus touches the transparent electrode structure 380, and the drive unit 350a may be driven by such electrical signals. The transparent electrode structure 380 may include the transparent conductor according to the embodiment, and may include, e.g., a touch panel screen. The transparent electrode structure 380 may be formed by patterning a flexible conductive conductor, and may include first sensor electrodes and second sensor electrodes each formed between the first sensor electrodes and intersecting the first sensor electrodes. The transparent electrode structure 380 may include a conductive material, e.g., metal nanowires, conductive polymers, and carbon nanotubes.

The window layer 390 may be formed as an outermost layer of the optical display 300 to protect the display.

In an implementation, adhesive layers may be further formed between the display unit 350a and the polarizing plate 370, between the polarizing plate 370 and the transparent electrode structure 380, and/or between the transparent electrode structure 380 and the window layer 390 to reinforce bonding between the display unit, the polarizing plate, the transparent electrode structure, and the window layer. The adhesive layers may be formed of an adhesive composition that includes, e.g., a (meth)acrylic resin, a curing agent, an initiator, and a silane coupling agent.

The (meth)acrylic resin may be a (meth)acrylic copolymer having an alkyl group, a hydroxyl group, an aromatic group, a carboxylic group, an alicyclic group, or a hetero-alicyclic group, and may include a typical (meth)acrylic copolymer. Specifically, the (meth)acrylic resin may be formed of a monomer mixture including at least one of a (meth)acrylic monomer containing a C₁ to C₁₀ unsaturated alkyl group, a (meth)acrylic monomer containing a C₁ to C₁₀ alkyl group having at least one hydroxyl group, a (meth)acrylic monomer containing a C₆ to C₂₀ aromatic group, a (meth)acrylic monomer containing a carboxylic group, a (meth)acrylic monomer containing a C₃ to C₂₀ alicyclic group, and a (meth)acrylic monomer containing a C₃ to C₁₀ hetero-alicyclic group having at least one of nitrogen (N), oxygen (O), and sulfur (S).

The curing agent may include, e.g., polyfunctional (meth)acrylates including a bi-functional (meth)acrylate such as hexanediol diacrylate; a tri-functional (meth)acrylate such as trimethylol propane tri(meth)acrylate; a tetra-functional (meth)acrylate such as pentaerythritol tetra(meth)acrylate; a penta-functional (meth)acrylate such as dipentaerythritol penta(meth)acrylate; and a hexa-functional (meth)acrylate such as dipentaerythritol hexa(meth)acrylate.

The photo-initiator may be a suitable photo-initiator and may include a photo-radical initiator.

The silane coupling agent may include, e.g., an epoxy group-containing silane coupling agent such as 3-glycidoxypropyltrimethoxysilane.

The adhesive composition may include, e.g., 100 parts by weight of the (meth)acrylic resin, about 0.1 to about 30 parts by weight of the curing agent, about 0.1 to about 10 parts by weight of the photo-initiator, and about 0.1 to about 20 parts by weight of the silane coupling agent. Within these content ranges, the adhesive layers formed of the adhesive composition can sufficiently bond the optical devices.

Each of the adhesive layers may have a thickness of about 10 μm to about 100 μm. Within this thickness range, the adhesive layers can sufficiently bond the optical devices.

In an implementation, a polarizing plate may be further disposed under the display unit 350a to realize polarization of internal light. For example, another polarizing plate may be disposed on a side of the display unit 350a that is opposite to the side on which the window layer 390, the transparent electrode structure 380, and the polarizing plate 370 are disposed.

Next, an optical display according to another embodiment will be described with reference to FIG. 7. FIG. 7 illustrates a sectional view of an optical display according to another embodiment.

Referring to FIG. 7, an optical display 400 according to another embodiment may include, e.g., a display unit 350a, a transparent electrode structure 380 formed on the display unit 350a, a polarizing plate 370 formed on the transparent electrode structure 380, and a window layer 390 formed on the polarizing plate 370. The transparent electrode structure 380 may include the transparent conductor according to the embodiments above. The optical display 400 according to this embodiment is substantially the same as the optical display 300 according to the above embodiment except that the transparent electrode structure 380 may be directly formed on the display unit 350a. For example, the transparent electrode structure 380 may be between the display unit 350a and the polarizing plate 370.

With the structure wherein the transparent electrode structure 380 is formed on the display unit 350a, the optical display 400 according to this embodiment may have a desirably smaller thickness and may exhibit improved visibility. The transparent electrode structure 380 may be formed by, e.g., deposition.

In an implementation, adhesive layers may be further formed between the display unit 350a and the transparent electrode structure 380, between the transparent electrode structure 380 and the polarizing plate 370 and/or between the polarizing plate 370 and the window layer 390 in order to reinforce the optical display. The adhesive layers may be formed of an adhesive composition that includes a (meth)acrylic resin, a curing agent, an initiator, and a silane coupling agent. The adhesive composition may be the same as described above.

In an implementation, a polarizing plate may be further disposed under the display unit 350a to help improve image quality of the optical display through polarization of internal light.

Next, an optical display according to a further embodiment will be described with reference to FIG. 8. FIG. 8 illustrates a sectional view of an optical display according to a further embodiment.

Referring to FIG. 8, an optical display 500 according to a further embodiment may include a display unit 350b, an adhesive layer 360 formed on the display unit 350b, and a window layer 390 formed on the adhesive layer 360, wherein the display unit 350b includes a transparent electrode structure. The transparent electrode structure may include the transparent conductor according to the embodiments above. The optical display 500 according to this embodiment is substantially the same as the optical display 300 according to the above embodiment except that the optical display 500 may be driven by the display unit 350b alone and the transparent electrode structure is included in the display unit 350b.

The display unit 350b may include a substrate and an optical device including an OLED, an LED, or an LCD formed on the substrate. In an implementation, the transparent electrode structure 380 may be formed inside the display unit 350b. In an implementation, the transparent electrode structure 380 may include the transparent conductor according to the embodiments above, e.g., a touch panel screen.

In an implementation, an adhesive layer may be further formed between the display unit 350b and the window layer 390 in order to reinforce the optical display. The adhesive layer may be formed of an adhesive composition that includes a (meth)acrylic resin, a curing agent, an initiator, and a silane coupling agent. The adhesive composition is the same as described above.

In an implementation, a polarizing plate may be further disposed under the display unit 350b to help improve image quality of the optical display through polarization of internal light.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.′

### Example 1

Preparation of conductive composition: An acetic acid aqueous solution (concentration: 1.0%, based on weight) was added to 50 parts by weight of a metal nanowire-containing solution (ClearOhm Ink, metal nanowires: 0.5 parts by weight) and 50 parts by weight of deionized water such that the acetic acid aqueous solution was present in an amount of 3.0 wt % in the conducive composition, followed by stirring, thereby preparing a conductive composition. The acetic acid aqueous solution was prepared by adding 1 g of purity 100% acetic acid to 99 g of water.

Preparation of matrix composition: 1 part by weight of a mixture, which consisted of 38.5 parts by weight of dipentaerythritol hexaacrylate (SK CYTEC Co., Ltd.), 13.0 parts by weight of ethoxylated trimethylolpropane triacrylate (SARTOMER Chemicals), 34.5 parts by weight of inorganic hollow silica nanoparticles (XJA-2502-LR, average particle diameter: 60 nm, refractive index:1.36), 1.0 part by weight of a mixture of a phenol-based antioxidant (Irganox 1010) and a phosphorus-based antioxidant (Irgafos 168, BASF Co., Ltd.), 8.5 parts by weight of an adhesion enhancer (KBE-903, SHIN-ETSU Chemical Co., Ltd.), 4.5 parts by weight of an initiator (Irgacure 184, CIBA Specialty Chemicals Co., Ltd.), was mixed with 99 parts by weight of methyl isobutyl ketone, thereby preparing a matrix composition.

Fabrication of transparent conductor: The prepared conductive composition was coated onto a 50 μm thick polycarbonate (PC) film (Tejin Co., Ltd.) using a spin coater, followed by drying in an oven at 80° C. for 90 seconds and at 110° C. for 90 seconds to form a metal nanowire network. Then, the prepared matrix composition was coated onto the metal nanowire network using a spin coater, and dried in an oven at 80° C. for 2 minutes and at 110° C. for 2 minutes, followed by nitrogen treatment for 2 minutes. Then, the matrix composition was subjected to UV curing at 300 mJ/cm², thereby providing a transparent conductor having a conductive layer (thickness: 80 nm) stacked thereon.

### Example 2

A transparent conductor was fabricated in the same manner as in Example 1 except that the acetic acid aqueous solution was present in an amount of 1.0 wt % in the conductive composition and 0.003 wt % of an ammonium chloride aqueous solution (concentration: 0.01%, based on weight) was further added to the conductive composition. The ammonium chloride aqueous solution was prepared by adding 0.01 g of ammonium chloride to 99.99 g of water.

### Example 3

A transparent conductor was fabricated in the same manner as in Example 2 except that the acetic acid aqueous solution was present in an amount of 2.0 wt % in the conductive composition.

### Example 4

A transparent conductor was fabricated in the same manner as in Example 2 except that the acetic acid aqueous solution was present in an amount of 3.0 wt % in the conductive composition.

### Example 5

A transparent conductor was fabricated in the same manner as in Example 4 except that 0.005 wt % of a sodium chloride aqueous solution (concentration: 0.1%, based on weight) was further added to the conductive composition.

### Example 6

A transparent conductor was fabricated in the same manner as in Example 1 except that 2.0 wt % of a formic acid aqueous solution (concentration: 1.0%, based on weight) was added instead of the acetic acid aqueous solution.

### Example 7

A transparent conductor was fabricated in the same manner as in Example 2 except that 2.0 wt % of a lactic acid aqueous solution (concentration: 1.0%, based on weight) was added instead of the acetic acid aqueous solution.

### Comparative Example 1

A transparent conductor was fabricated in the same manner as in Example 1 except that 3.0 wt % of a sulfuric acid aqueous solution (concentration: 0.01%, based on weight) was added instead of the acetic acid aqueous solution.

### Comparative Example 2

A transparent conductor was fabricated in the same manner as in Example 1 except that 3.0 wt % of a sulfuric acid aqueous solution (concentration: 0.01%, based on weight) was added instead of the acetic acid aqueous solution and 0.03 wt % of an ammonium chloride aqueous solution (concentration: 0.01%, based on weight) was further added.

### Comparative Example 3

A transparent conductor was fabricated in the same manner as in Example 1 except that 3.0 wt % of a sulfuric acid aqueous solution (concentration: 0.01%, based on weight) was added instead of the acetic acid aqueous solution and 0.01 wt % of a sodium chloride aqueous solution (concentration: 0.01%, based on weight) was further added to the conductive composition.

### Comparative Example 4

A transparent conductor was fabricated in the same manner as in Example 1 except that 3.0 wt % of a nitric acid aqueous solution (concentration: 0.1%, based on weight) was added instead of the acetic acid aqueous solution.

### Comparative Example 5

A transparent conductor was fabricated in the same manner as in Example 2 except that 3.0 wt % of a nitric acid aqueous solution (concentration: 0.1%, based on weight) was added instead of the acetic acid aqueous solution.

### Comparative Example 6

A transparent conductor was fabricated in the same manner as in Comparative Example 4 except that 0.01 wt % of a sodium chloride aqueous solution (concentration: 0.1%, based on weight) was further added to the conductive composition.

### Comparative Example 7

A transparent conductor was fabricated in the same manner as in Example 1 except that 3.0 wt % of an ammonia aqueous solution (concentration: 1.0%, based on weight) was added instead of the acetic acid aqueous solution.

Property Evaluation

Each of the transparent conductors of the Examples and Comparative Examples was evaluated as to the following properties and results are shown in Tables 1 and 2.

(1) Haze (%) and total transmittance (%): Haze and total transmittance were measured at a wavelength of 400 nm to 700 nm using a haze meter (NDH-9000) for the transparent conductor.

(2) Transmittance b* value: Transmittance color coordinates were measured at a wavelength of 400 nm to 700 nm using a colorimeter (CM3600A, Konica Minolta Co., Ltd.) for the transparent conductor.

(3) Sheet resistance (Ω/□): Sheet resistance was measured on a surface of each transparent conductor (not patterned) using a non-contact type sheet resistance meter (EC-80P, NAPSON Co., Ltd.).

(4) Sheet resistance change rate (%): A 125 μm thick transparent adhesive film (Optically Clear Adhesives 8215, 3M) and a 100 μm thick PET film (A4300, Toyobo Co., Ltd.) were sequentially stacked on each of the transparent conductors in order to prepare a sample for measurement of resistance variation. Initial sheet resistance (a) was measured on the prepared sample using a non-contact type sheet resistance meter (EC-80P, NAPSON Co., Ltd.) and sheet resistance (b) was measured by the same method after leaving the sample under conditions of 85° C. and 85% relative humidity for 240 hours. Sheet resistance change rate was evaluated by the following Equation 1. A sheet resistance change rate of 10% or less indicates good reliability:

Sheet resistance change rate=|b−a|/a×100, [Equation 1]

In Equation 1, a is the initial sheet resistance of the transparent conductor and b is the sheet resistance of the transparent conductor after being left under conditions of 85° C. and 85% relative humidity for 240 hours.

TABLE 1

| Item | | Example 1 | Example 2 | Example 3 | Example 4 | Example 5 | Example 6 | Example 7 |
|---|---|---|---|---|---|---|---|---|
| A | Acetic | 3.0 | 1.0 | 2.0 | 3.0 | 3.0 | — | — |
| (wt %) | acid | | | | | | | |
| | aqueous | | | | | | | |
| | solution | | | | | | | |
| | Formic | — | — | — | — | — | 2.0 | — |
| | acid | | | | | | | |
| | aqueous | | | | | | | |
| | solution | | | | | | | |
| | Lactic acid | — | — | — | — | — | — | 2.0 |
| | aqueous | | | | | | | |
| | solution | | | | | | | |
| B | NH₄Cl | — | 0.003 | 0.003 | 0.003 | 0.003 | — | 0.003 |
| (wt %) | aqueous | | | | | | | |
| | solution | | | | | | | |
| | NaCl | — | — | — | — | 0.005 | — | — |
| | aqueous | | | | | | | |
| | solution | | | | | | | |

| | | | | | | | |
|---|---|---|---|---|---|---|---|
| Haze (%) | 1.01 | 1.19 | 1.09 | 1.04 | 1.05 | 1.12 | 1.13 |
| Total | 91.08 | 90.96 | 91.03 | 91.03 | 90.95 | 91.06 | 91.04 |
| Transmittance (%) | | | | | | | |
| Transmittance b* | 0.95 | 1.05 | 0.96 | 0.96 | 1.00 | 1.08 | 1.02 |
| value | | | | | | | |
| Sheet resistance | 31.21 | 33.43 | 33.12 | 35.65 | 36.38 | 29.60 | 32.20 |
| (Ω/□) | | | | | | | |
| Sheet resistance | 7.4 | 8.8 | 7.5 | 9.4 | 2.7 | 8.9 | 9.2 |
| change rate (%) | | | | | | | |

TABLE 2

| | | Comparative | Comparative | Comparative | Comparative | Comparative | Comparative | Comparative |
|---|---|---|---|---|---|---|---|---|
| Item | | Example 1 | Example 2 | Example 3 | Example 4 | Example 5 | Example 6 | Example 7 |
| A | Sulfuric | 3.0 | 3.0 | 3.0 | — | — | — | — |
| (wt %) | acid | | | | | | | |
| | aqueous | | | | | | | |
| | solution | | | | | | | |
| | Nitric acid | — | — | — | 3.0 | 3.0 | 3.0 | — |
| | aqueous | | | | | | | |
| | solution | | | | | | | |
| | Ammonia | — | — | — | — | — | — | 3.0 |
| | aqueous | | | | | | | |
| | solution | | | | | | | |
| B | NH₄Cl | — | 0.003 | — | — | 0.003 | — | — |
| (wt %) | aqueous | | | | | | | |
| | solution | | | | | | | |
| | NaCl | — | — | 0.01 | — | — | 0.01 | — |
| | aqueous | | | | | | | |
| | solution | | | | | | | |

| | | | | | | | |
|---|---|---|---|---|---|---|---|
| Haze (%) | 1.05 | 1. | 1.16 | 1.23 | 1.21 | 1.20 | 1.05 |
| Total | 90.88 | 90.75 | 90.76 | 90.72 | 90.63 | 90.82 | 90.75 |
| Transmittance (%) | | | | | | | |
| Transmittance b* | 1.12 | 1.15 | 1.14 | 1.13 | 1.15 | 1.16 | 1.17 |
| value | | | | | | | |
| Sheet resistance | Unmeasurable | Unmeasurable | Unmeasurable | Unmeasurable | Unmeasurable | Unmeasurable | Unmeasurable |
| (Ω/□) | | | | | | | |
| Sheet resistance | Unmeasurable | Unmeasurable | Unmeasurable | Unmeasurable | Unmeasurable | Unmeasurable | Unmeasurable |
| change rate (%) | | | | | | | |

In Table 1, it may be seen that all of the transparent conductors of Examples 1 to 7 exhibited good properties in terms of haze, transmittance, and transmittance b* value, and had a sheet resistance change rate of 10% or less indicating good reliability.

Conversely, in Table 2, it may be seen that the transparent conductors of Comparative Examples 1 to 3, 6, and 7 had high transmittance b* values (to become yellow), and the transparent conductors of Comparative Examples 4 and 5 suffered from deterioration in optical properties such as haze and transmittance b* value, and rapid increase in sheet resistance due to oxidation of the metal nanowires, thereby providing unmeasurable sheet resistance and unmeasurable sheet resistance change rate.

The embodiments may provide a transparent conductor including silver nanowires that may have the same or better optical properties at low resistance as at high resistance in order to ensure touch sensing accuracy and rapid response time and to be fabricated into a large touch panel.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A transparent conductor, comprising:
a base layer; and
a conductive layer on the base layer,
wherein:
the conductive layer includes metal nanowires and a matrix, and
the transparent conductor has:
a haze of about 1.2% or less, a total transmittance of about 88% or more, a transmittance b* value of about 1.10 or less, as measured at a wavelength of 400 nm to 700 nm, and
a sheet resistance of about 50Ω/□ or less.

2. The transparent conductor as claimed in claim 1, wherein the transparent conductor has a sheet resistance change rate of about 10.0% or less, as calculated by Equation 1:
Sheet resistance change rate=|b−a|/a×100, [Equation 1]
wherein, in Equation 1,
a is initial sheet resistance of the transparent conductor, and
b is sheet resistance of the transparent conductor after being left under conditions of 85° C. and 85% relative humidity for 240 hours.

3. The transparent conductor as claimed in claim 1, wherein the metal nanowires include silver, copper, platinum, tin, iron, nickel, cobalt, aluminum, zinc, indium, or titanium.

4. The transparent conductor as claimed in claim 1, further comprising an overcoating layer on the conductive layer.

5. The transparent conductor as claimed in claim 1, further comprising a hard coating layer, an anti-corrosion layer, an anti-reflection layer, an anti-glare layer, an adhesion enhancing layer, or a barrier layer, on one or both surfaces of the base layer.

6. A method of fabricating a transparent conductor, the method comprising:
forming a metal nanowire network on a base layer using a conductive composition; and
forming a conductive layer on the metal nanowire network using a matrix composition,
wherein the conductive composition includes an acid and metal nanowires.

7. The method of fabricating a transparent conductor as claimed in claim 6, wherein the conductive composition further includes a chloride ion-containing compound.

8. The method of fabricating a transparent conductor as claimed in claim 7, wherein the chloride ion-containing compound includes at least one of ammonium chloride, sodium chloride, and potassium chloride.

9. The method of fabricating a transparent conductor as claimed in claim 6, wherein the acid is an acid solution having a pH of about 2 to about 6.

10. The method of fabricating a transparent conductor as claimed in claim 6, wherein the acid includes acetic acid, formic acid, or lactic acid.

11. The method of fabricating a transparent conductor as claimed in claim 6, wherein the metal nanowires include silver, copper, platinum, tin, iron, nickel, cobalt, aluminum, zinc, indium, or titanium.

12. The method of fabricating a transparent conductor as claimed in claim 6, further comprising forming an overcoating layer on the conductive layer.

13. An optical display comprising the transparent conductor as claimed in claim 1.

14. The optical display as claimed in claim 13, wherein the optical display includes:
a display unit;
a polarizing plate on the display unit;
a transparent electrode structure on the polarizing plate; and
a window layer on the transparent electrode structure,
wherein the transparent electrode structure includes the transparent conductor.

15. The optical display as claimed in claim 14, further comprising another polarizing plate on a side of the display unit that is opposite to the side of the display unit on which the polarizing plate, the transparent electrode structure, and the window layer are disposed.

16. The optical display as claimed in claim 13, wherein the optical display includes:
a display unit;
a transparent electrode structure on the display unit;
a polarizing plate on the transparent electrode structure; and
a window layer on the polarizing plate,
wherein the transparent electrode structure includes the transparent conductor.

17. The optical display as claimed in claim 16, further comprising another polarizing plate on a side of the display unit that is opposite to the side of the display unit on which the transparent electrode structure, the polarizing plate, and the window layer are disposed.

18. The optical display as claimed in claim 13, wherein the optical display includes:
a display unit; and
a window layer on the display unit, wherein the display unit includes a transparent electrode structure, the transparent electrode structure including the transparent conductor.

19. The optical display as claimed in claim 18, further comprising a polarizing plate on an upper side or a lower side of the display unit.
